(19) United States
(12) Patent Application Publication
(10) Pub. No.: US 2009/0278262 A1
(43) Pub. Date: Nov. 12, 2009

(54) Multi-chip package including component supporting die overhang and system including same

(76) Inventors: Boon Keat Tan, Penang (MY); Sze Mai Ooi, Penang (MY)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/151,911

(22) Filed: May 9, 2008

(51) Int. Cl. H01L 23/538

(52) U.S. Cl. 257/777; 257/E23.169

(57) ABSTRACT

A microelectronic package and a system including the package. The package includes: a substrate; a stack of dice electrically and mechanically bonded to the substrate, the stack including a second level die and a first level die between the substrate and the second level die, the second level die defining an overhang; and a component disposed between the substrate and the overhang of the second level die and adapted to support the overhang on the substrate.

### FIELD

Embodiments of the present invention relate generally to the field of microelectronic fabrication, and in particular to the fabrication of a multi-chip package presenting a die overhang.

### BACKGROUND

Multi-chip stacked packages or multi-chip modules (MCM) are well known in the art, and typically include a substrate, such as an organic or ceramic substrate, supporting a stack of dice thereon. The use of MCM's presents a trend in electronic packaging as it allows the integration of multiple functionalities onto a single package. A prior art example of such a package is shown in FIG. 1. As seen in FIG. 1, a MCM 100 may include a substrate 102 and a stack 104 of dice, including a first level C4 die 106, a second level die 108 and a third level die 110. The dies in the stack 104 may be mechanically bonded together by way of die attach paste or via film attach (not shown). MCM's of the prior art may have any number of dice stacked thereon, although MCM 100 includes only three such dice. Charge is supplied to the first level die 106 by way of a C4 connection including solder balls 112, and charge is supplied to the upper level dice by way of wirebonds 114. Charge is supplied to the wirebonds 114 through the substrate 102. Substrate 102 in turn may be connected to a PCB (not shown) by way of a BGA 118. The MCM 100 may further include additional microelectronic devices on substrate 102, such as, for example, a multi-level ceramic capacitor (MLCC) 120 mounted onto the substrate 102. The second level die 108 presents an overhang 122 on each side of the first level C4 die 106 as shown. However, since MCM's usually involve the use of thin dies, and this in order to limit the overall Z-height of the stacked die package of the MCM. However, a disadvantage of using thinner dies is that it limits the die overhang, such as overhang 122 in order to address and prevent possible failure as a result of mechanical stresses at the overhang areas. A limiting of the die overhang to a certain length however disadvantageously limits the die stacking options in the MCM.

The prior art fails to provide a MCM where the extent of the overhang of the second level die is not limited.

### BRIEF DESCRIPTION OF THE DRAWINGS

FIG. 1 is a cross-sectional view of a conventional MCM including a MLCC thereon;

FIG. 2 is a perspective view of a MCM according to an embodiment;

FIG. 3 is a cross-sectional view of a MCM according to an embodiment;

FIG. 4 is a schematic view of an embodiment of a system incorporating a MCM according to an embodiment.

For simplicity and clarity of illustration, elements in the drawings have not necessarily been drawn to scale. For example, the dimensions of some of the elements may be exaggerated relative to other elements for clarity. Where considered appropriate, reference numerals have been repeated among the drawings to indicate corresponding or analogous elements.

### DETAILED DESCRIPTION

In the following detailed description, a MCM and a system including the MCM are disclosed. Reference is made to the accompanying drawings within which are shown, by way of illustration, specific embodiments by which the present invention may be practiced. It is to be understood that other embodiments may exist and that other structural changes may be made without departing from the scope and spirit of the present invention.

The terms on, above, below, and adjacent as used herein refer to the position of one element relative to other elements. As such, a first element disposed on, above, or below a second element may be directly in contact with the second element or it may include one or more intervening elements. In addition, a first element disposed next to or adjacent a second element may be directly in contact with the second element or it may include one or more intervening elements. In addition, in the instant description, figures and/or elements may be referred to in the alternative. In such a case, for example where the description refers to Figs. X/Y showing an element A/B, what is meant is that Fig. X shows element A and Fig. Y shows element B. In addition, a “layer” as used herein may refer to a layer made of a single material, a layer made of a mixture of different components, a layer made of various sub-layers, each sub-layer also having the same definition of layer as set forth above.

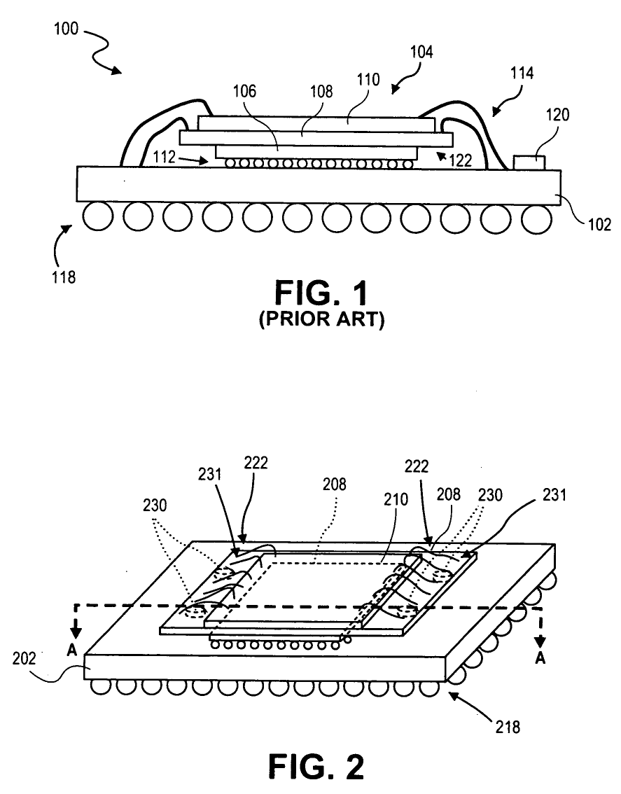

Aspects of this and other embodiments will be discussed herein with respect to FIGS. 2-4 below. The figures, however, should not be taken to be limiting, as it is intended for the purpose of explanation and understanding.

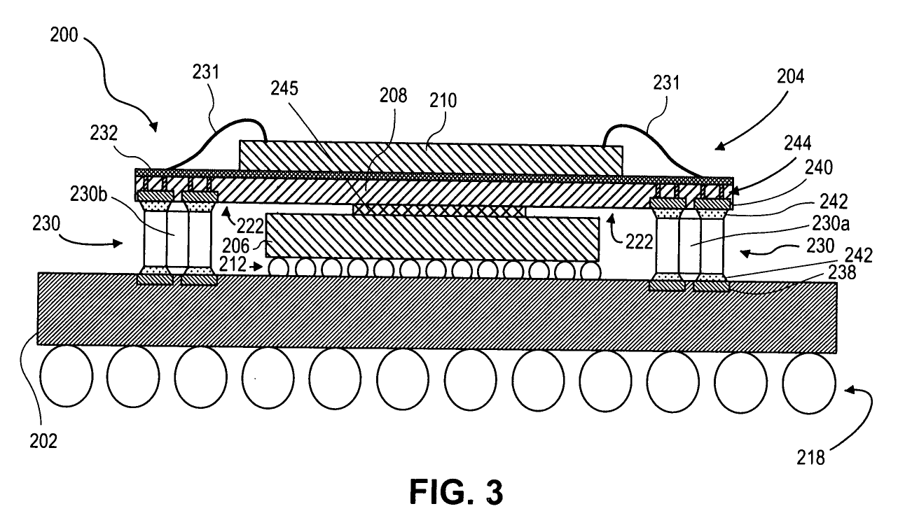

Referring first to FIGS. 2 and 3, a MCM 200 according to an embodiment may includes a substrate 202 and a stack 204 of dice, including a first level C4 die 206, a second level die 208 and a third level die 210. The stack 204 is electrically and mechanically bonded to the substrate. An electrical and mechanical bonding of stack 204 to substrate 202 may be effected for example by way of a C4 connection with respect to the first level die 206, and further by way of component 230 as will be explained in further detail in the paragraph below. A MCM according to embodiments may include any number of dice, although a three-die MCM is depicted in FIGS. 2 and 3. The second level die 208 may be mechanically bonded to the first level die 206 by way of a conventional die attach paste 245, and the third level die 210 may be bonded to the substrate 202 and/or the second level die 208 in a number of ways according to embodiments. In the shown embodiment, the third level die is mechanically bonded to the second level die 208 by way of die attach paste of film attach (not shown), and electrically bonded to the second level die 208 by way of wirebonds 231. However, embodiments also include within their scope an electrical bonding of the third level die 210 to the substrate 202 by way of wirebonds (not shown), or a mechanical and electrical bonding of the third level die 210 to the second level die by way of a C4 connection (not shown).

As shown in FIG. 3, charge may be supplied to the first level die 206 by way of a C4 connection including solder balls 212, while charge may be supplied to the second level die 208 by way of component 230 as will be explained in further detail in the paragraph below. Hereinafter, “component 230” may refer to one ore a plurality of components as defined further below. Substrate 202 in turn may be connected to a PCB (not shown) by way of a BGA 218. The second level die 208 is shown as presenting an overhang 222 on each side of the first level C4 die 206 as shown. It is noted that, although embodiments are described in relation to the figures mention the overhang only with respect to a second level die, embodiments are not so limited, and include within their scope the provision of a component to support the overhang of any upper level die, including (for example) the second level die of a stack of dice.

According to embodiments, in order to address and prevent possible failure of the package as a result of mechanical stresses at the overhang 222, component 230 may be placed under the overhang 222, that is, between substrate 202 and the overhang 222. As seen in the figures, overhang 222 of second level die 208 extends beyond the vertical limits of the first level die 206 at each side thereof, although embodiments comprise within their scope an overhang which may present itself beyond any one of vertical limits of the first level die. According to embodiments, a “component adapted to support the overhang” refers to any component which is adapted to provide structural support to the overhang transferring at least some of the load from the overhang onto the underlying substrate. Thus, a “component adapted to support the overhang on the substrate” as used herein may include, for example, any of: (1) a solid component providing structural support for the overhang without other functionality of the component; and/or (2) a solid component as noted above, with the added functionality of providing electrical coupling between the substrate and the stack of dice; and/or (3) a functional component in the form of a microelectronic device (including, for example, a capacitor including a Multi-Level Ceramic Capacitor (MLCC), an On-Package-Voltage-Regulation device (OPVR), an Integrated Semiconductor Voltage Regulator (ISVR), a Dynamic Random Access Memory (DRAM), or a resistor, to name only a few; and/or (4) a microelectronic device as noted above which also provides electrical coupling between the substrate and the stack of dice. Thus, although the embodiment of FIG. 3 merely shows a component of the fourth kind as noted in item (4) above, embodiments in general are not so limited.

As seen in FIG. 2, according to one embodiment, the component 230 may include a plurality of components, including any of the types of components listed in items (1)-(4) above, disposed at distinct regions of the overhang 222 to provide support for those distinct regions on the substrate. According to one embodiment, such components (schematically depicted in FIG. 2 in broken lines as box-like shapes) may be distributed between the substrate 202 and second level die 208 in a manner to optimize load distribution from the overhang 222 onto the substrate 202 as a function of the available number and load-bearing characteristics of each of the components. As also seen in FIG. 2, embodiments do include within their scope the use of wirebonds, such as wirebonds 231, between the second level die 208 and the third level die 210.

Referring now to FIG. 3, a cross-section is shown through line A-A in FIG. 2, with the exception that the embodiment of FIG. 3 does not show the wirebonds of FIG. 2. As seen in FIG. 3, component 230 may include a plurality of components at each region of the overhang 222 being supported. In the shown embodiment, component 230 includes a pair of component 230a at one side of first level die 206, and another component 230b at another side of first level die 206 as shown. It is understood that the depiction in FIG. 3, by virtue of representing a cross-section through FIG. 2, does not show the other ones of components 230 in FIG. 2. However, reference herein to components 230a and/or 230b may be extended to the other components 230 of FIG. 2 not shown in FIG. 3. In the shown embodiment, components 230a and 230b of FIG. 3 are identical, and comprise MLCC's, although it is to be understood that, as suggested above, embodiments are not so limited.

According to a preferred embodiment, as shown in FIG. 3, each of the components 230a and 230b not only provide structural support for the overhang 222, but are also functional components (in this case, MLCC's), and, in addition, are adapted to allow an electrical coupling of the substrate 202 at least to the second level die 208 therethrough. In this way, package 200 is configured to electrically couple substrate 202 to the second level die 208 through the components 230a and 230b. An electrical coupling of the components 230a and 230b to the substrate 202 and second level die 208 may be effected by coupling terminals on each component 230a and 230b to substrate component pads 238 on the substrate, and to die component pads 240 on the second level die 208, the coupling occurring by way of example by way of solder 242 as shown. For example, the component pads 238 and/or 240 may be square shaped, with a x dimension of about 440 microns, a y dimension of about 440 microns, having respective solder resist openings with a x dimension of about 300 microns, and a y dimension of about 300 microns. Pad design may be similar for component pads 238 and 240.

Referring still to FIG. 3, according to an embodiment, the stack 204 may include the third level die 210 as shown disposed on the second level die 208. As also shown in FIG. 3, the second level die 208 may include one or more through-vias, such as through vias 244 extending therethrough to power grid 232. In the shown configuration, the power grid 232 is electrically coupled to the through vias 244, and the second level die 208 is electrically coupled to the power grid 232. In the shown embodiment, the third level die 210 is electrically bonded to the power grid 232 by way of wirebonds 231, although a C4 connection (not shown), or any other suitable arrangement for electrically coupling the third level die 210 to the power grid 232 may be used instead. In the shown embodiment, the second level die 208 and the third level die 210 may be powered through the component 230 (here, components 230a and 230b), the through vias 244, and the power grid 232.

According to embodiments, one may ensure a selection of the component height which fits the die overhang stackup height to be able to support the die overhang portion. For example, if the gap between the overhang die and the substrate is X mm, the height of each component 230, such as MLCC's 230a and 230b, would need to be selected to be equal to X—(2× solder paste thickness), assuming that the top and bottom solder paste thicknesses are substantially equal. A selection of the thickness of the first level die is also a factor in ensuring that the component, such as the MLCC's 230a and 230b, are able to fit between the die overhang and substrate. For example, a die thickness for the first level die may be equal to about 280 microns, a height of solder balls 212 may be about 75 microns, a thickness of the die attach paste 245 may be about 25 microns, while the height of each MLCC 230a and 230b may be about 300 microns, and the thickness of each of the solder 242 may be about 40 microns for a fit to occur between MLCC's 230a and 230b on the one hand, and the distance between a surface of substrate 202 facing the overhang 222 and a surface of the overhang 222 facing the substrate 202 on the other hand.

A method embodiment for providing a package such as package 200 of FIGS. 2 or 3 will now be described.

According to a method embodiment, a substrate may first be flux printed, and then provided with a solder paste thereon prior to the placement of a component, such as MLCC's thereon. Solder pastes with a higher melting point, such as, for example, Sn95.8Ag3.5Cu0.7 (melting point of about 217 degrees Celsius) may be used as the solder paste for the bonding of MLCC's, and as the C4 solder material for the first level die. After provision of the solder paste, the component and the first level die (C4 die) may be placed on the substrate. Thereafter, solder reflow may be performed for MLCC attach and first level die attach. Thereafter, any flux trapped between the first level die and the substrate may be removed. After flux removal, an epoxy underfill material may be dispensed to fill a cavity under and at the perimeter of the first level die, and then cured. Thereafter, solder paste may be applied to die-side terminals of the MLCC's attached to the substrate. Here, the solder paste may include a material having a lower melting point than the solder paste used for MLCC and first level die attach to the substrate, such as, for example, Sn88Ag3.5Bi0.5In8 (melting point of about 197 degrees Celsius). The above is to ensure that the earlier solder paste between the MLCC and substrate does not reflow together with the solder paste between the MLCC and the second level die. Thereafter, die attach material may be applied on top of first level die, and the second level die may be placed on top of the first level die. A second reflow may then be effected at lower temperature than the first reflow to enable the MLCC's to attach to the second level die and the second level die to attach to first level die. If applicable, other dies may be attached and stacked using a wire bonding process.

Advantageously, embodiments provide a package where a component, preferably a microelectronic component such as a MLCC, is placed between a substrate and an overhang of an upper level die to support the overhang on the substrate. In this way, mechanical stresses present at the overhang region are mitigated, and, as a result, die cracking may be substantially obviated, in this way allowing the use of thinner dies with more extensive overhang in a MCM. In addition, an embodiment allows the routing of electrical signals, such as power signals, to the upper level die from the substrate through the component, in this way serving as a power decoupling solution to the die power requirements. Direct electrical coupling of the upper level die to the substrate through the component advantageously improves power delivery performance in terms of providing the switching current charge to the die with minimum loop inductance, and this because the component may be directly connected to die pads. Advantageously, placing the component under the die overhang does not take up additional space on the package substrate.

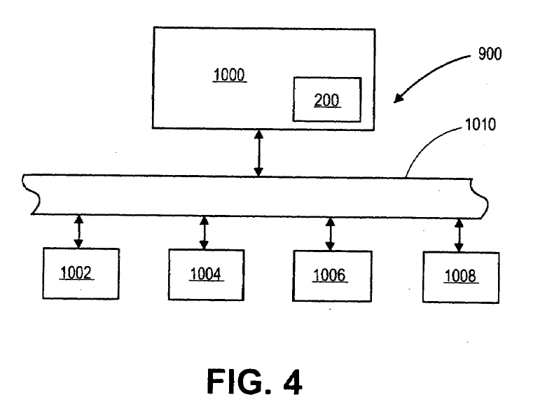

Referring to FIG. 4, there is illustrated one of many possible systems 900 in which embodiments of the present invention may be used. In one embodiment, the electronic assembly 1000 may include a microelectronic package, such as package 200 of FIG. 3. Assembly 1000 may further include a microprocessor. In an alternate embodiment, the electronic assembly 1000 may include an application specific IC (ASIC). Integrated circuits found in chipsets (e.g., graphics, sound, and control chipsets) may also be packaged in accordance with embodiments of this invention.

For the embodiment depicted by FIG. 4, the system 900 may also include a main memory 1002, a graphics processor 1004, a mass storage device 1006, and/or an input/output module 1008 coupled to each other by way of a bus 1010, as shown. Examples of the memory 1002 include but are not limited to static random access memory (SRAM) and dynamic random access memory (DRAM). Examples of the mass storage device 1006 include but are not limited to a hard disk drive, a compact disk drive (CD), a digital versatile disk drive (DVD), and so forth. Examples of the input/output module 1008 include but are not limited to a keyboard, cursor control arrangements, a display, a network interface, and so forth. Examples of the bus 1010 include but are not limited to a peripheral control interface (PCI) bus, and Industry Standard Architecture (ISA) bus, and so forth. In various embodiments, the system 90 may be a wireless mobile phone, a personal digital assistant, a pocket PC, a tablet PC, a notebook PC, a desktop computer, a set-top box, a media-center PC, a DVD player, and a server.

The various embodiments described above have been presented by way of example and not by way of limitation. Having thus described in detail embodiments of the present invention, it is understood that the invention defined by the appended claims is not to be limited by particular details set forth in the above description, as many variations thereof are possible without departing from the spirit or scope thereof.

What is claimed is:

1. A microelectronic package comprising:
a substrate;
a stack of dice electrically and mechanically bonded to the substrate, the stack including a second level die and a first level die between the substrate and the second level die, the second level die defining an overhang; and
a component disposed between the substrate and the overhang of the second level die and adapted to support the overhang on the substrate.

2. The package of claim 1, wherein the component comprises a microelectronic device.

3. The package of claim 2, wherein the device includes at least one of a Multi-Level Ceramic Capacitor (MLCC), an On-Package-Voltage-Regulation device (OPVR), an Integrated Semiconductor Voltage Regulator (ISVR), a Dynamic Random Access Memory (DRAM), and a resistor.

4. The package of claim 1, wherein the package is configured to electrically couple the substrate to the second level die through the component.

5. The package of claim 4, wherein:
the stack of dice includes a power grid; and
the component includes a terminal thereon electrically coupled to the power grid of the stack of dice.

6. The package of claim 4, wherein:
the substrate includes a substrate component pad thereon;
the second level die includes a die component pad thereon; and
the component is disposed between and electrically coupled to both the substrate-side component pad and the die-side component pad.

7. The package of claim 5, wherein:
the second level die includes:
a through-via extending therethrough, the component being electrically coupled to the through-via; and
a power grid at a surface thereof, the power grid being electrically coupled to the through-vias, and the second level die being electrically coupled to the power grid such that the second level die is adapted to be powered through the component, the through-via and the power grid.

8. The package of claim 7, wherein the stack further includes a third level die disposed on the second level die, the third level die being electrically coupled to at least one of the power grid and the substrate.

9. The package of claim 2, wherein the component comprises a plurality of components.

10. The package of claim 9, wherein the plurality of components are disposed at distinct regions of the overhang with respect to one another.

11. A system including:
an electronic assembly comprising:
a microelectronic package comprising:
a substrate;
a stack of dice electrically and mechanically bonded to the substrate, the stack including a second level die and a first level die between the substrate and the second level die, the second level die defining an overhang; and
a component disposed between the substrate and the overhand region of the second level die and adapted to support the overhang on the substrate; and
a main memory coupled to the electronic assembly.

12. The system of claim 11, wherein the component comprises a microelectronic device.

13. The system of claim 12, wherein the device includes at least one of a Multi-Level Ceramic Capacitor (MLCC), an On-Package-Voltage-Regulation device (OPVR), an Integrated Semiconductor Voltage Regulator (ISVR), a Dynamic Random Access Memory (DRAM), and a resistor.

14. The system of claim 11, wherein the package is configured to electrically couple the substrate to the second level die through the component.

15. The system of claim 14, wherein:
the stack of dice includes a power grid; and
the component includes a terminal thereon electrically coupled to the power grid of the stack of dice.
